(19) United States
(12) Patent Application Publication
(10) Pub. No.: US 2026/0144089 A1
(43) Pub. Date: May 21, 2026

(54) Integration of Passive Components in a Semiconductor Package

(71) Applicant: TEXAS INSTRUMENTS INCORPORATED, DALLAS, TX (US)

(72) Inventor: Naweed ANJUM, MURPHY, TX (US)

(21) Appl. No.: 18/951,093

(22) Filed: Nov. 18, 2024

(51) Int. Cl. H01L 23/495; H01L 23/31

(52) U.S. Cl. CPC H10W 70/429; H10W 74/111

(57) ABSTRACT

A semiconductor package includes a semiconductor die, a first trace, a second trace, and a passive component. The first trace has a proximate portion extending from a first proximate end, electrically connected to the semiconductor die, to a distal end. The first trace also includes a distal portion extending from the distal end to a first terminus at a package edge of the semiconductor package. The proximate portion has an attenuated thickness, and the distal portion has a full thickness greater than the attenuated thickness. The second trace extends from a second proximate end, electrically connected to the semiconductor die, to a second terminus at the package edge of the semiconductor package. The second trace has the attenuated thickness. The passive component electrically connected to the first trace and the second trace.

### TECHNICAL FIELD

This description relates to integrating passive components within a semiconductor package.

### BACKGROUND

Many types of semiconductor devices have input/output (I/O) pins that are used to connect external passive components. For example, a semiconductor die is attached to a lead frame and then surrounded by a mold compound to form a semiconductor package. The semiconductor package is then attached to a printed circuit board (PCB). A capacitor, inductor, or other type of passive component may be attached to the same PCB. The passive component is electrically connected to the semiconductor die through the PCB outside of the mold compound. A considerable amount of space is occupied by mounting the passive components external to the semiconductor package. Additionally, because the passive components are external to the semiconductor package, the passive components are easily discernable and subject to damage.

### SUMMARY

A first example is related to a semiconductor package. The semiconductor package includes a semiconductor die, a first trace, a second trace, and a passive component. The first trace has a proximate portion extending from a first proximate end, electrically connected to the semiconductor die, to a distal end. The first trace also includes a distal portion extending from the distal end to a first terminus at a package edge of the semiconductor package. The proximate portion has an attenuated thickness, and the distal portion has a full thickness greater than the attenuated thickness. The second trace extends from a second proximate end, electrically connected to the semiconductor die, to a second terminus at the package edge of the semiconductor package. The second trace has the attenuated thickness. The passive component is electrically connected to the first trace and the second trace.

A second example is related to a method of fabricating a semiconductor package. The method includes providing a lead frame having a first trace and a second trace. The first trace has a proximate portion extending from a first proximate end to a distal end. The first trace also has a distal portion extending from the distal end to a first terminus. The proximate portion has an attenuated thickness, and the distal portion has a full thickness greater than the attenuated thickness. The second trace extends from a second proximate end to a second terminus. The second trace has the attenuated thickness. The method also includes electrically connecting a semiconductor die to the first proximate end of the first trace and the second proximate end of the second trace. The method further includes affixing a passive component to a first joint of the proximate portion of the first trace and a second joint of the second trace. The method yet further includes encapsulating, at least in part, the semiconductor die, the first trace, the second trace, and the passive component in a mold compound that forms a package edge of the semiconductor package.

A third example is related to a method of fabricating a semiconductor package. The method includes providing a lead frame having a first trace and a second trace. The method also includes etching a proximate portion of the first trace to an attenuated thickness. The proximate portion extends from a first proximate end to a distal end. The first trace further comprises a distal portion extending from the distal end to a first terminus having a full thickness greater than the attenuated thickness. The method also includes etching the second trace to the attenuated thickness. The second trace extends from a second proximate end to a second terminus. The method further includes electrically connecting a semiconductor die to the first proximate end of the first trace and the second proximate end of the second trace. The method yet further includes affixing a passive component to a first joint of the proximate portion of the first trace and a second joint of the second trace. The method includes encapsulating, at least in part, the semiconductor die, the first trace, the second trace, and the passive component in a mold compound that forms a package edge of the semiconductor package.

### BRIEF DESCRIPTION OF THE DRAWINGS

FIG. 1 illustrates a perspective view of an example of a semiconductor package with an integrated passive component.

FIG. 2 illustrates a cross-sectional view of the semiconductor package with an integrated passive component of FIG. 1.

FIG. 3 illustrates an example of semiconductor devices ready for packaging on a lead frame with a strip layout.

FIG. 4 illustrates an example of a semiconductor package with a branching trace configuration.

FIG. 5 illustrates an example of semiconductor packages with a shared trace configuration.

FIG. 6 illustrates an example of a first stage of a method for forming a semiconductor package with an integrated passive component.

FIG. 7 illustrates an example of a second stage of the method for forming the semiconductor package with an integrated passive component.

FIG. 8 illustrates an example of a third stage of the method for forming the semiconductor package with an integrated passive component.

FIG. 9 illustrates an example of a fourth stage of the method for forming the semiconductor package with an integrated passive component.

FIG. 10 illustrates an example of a fifth stage of the method for forming the semiconductor package with an integrated passive component.

FIG. 11 illustrates an example of a sixth stage of the method for forming the semiconductor package with an integrated passive component.

FIG. 12 illustrates an example of a seventh stage of the method for forming the semiconductor package with an integrated passive component.

FIG. 13 illustrates a flowchart of an example method for forming the semiconductor package with an integrated passive component.

### DETAILED DESCRIPTION

Passive components are typically electrically connected to the semiconductor die at a point external to the semiconductor package to fabricate a device. However, externally mounting passive components to the semiconductor package consumes considerable amount of space in the device. To accommodate the space constraints of the device, the passive device may be integrated in a vertical arrangement. For example, a multi-layer substrate, such as a printed circuit board (PCB) is fabricated with a passive component on one level, which is concealed by another layer having pins that are externally accessible. However, stacked substrates are expensive and require custom designs to determine the stacked layout.

The disclosed examples are directed to a semiconductor package with an integrated passive component using a carrier, such as a lead frame. For example, the passive component is affixed across multiple traces of the lead frame that are contained within the semiconductor package. To prevent the passive component from being shorted, at least a portion of one trace of the multiple traces is etched to attenuated thickness such that the etched trace does not form a pin on the edge of the semiconductor package. Accordingly, by etching the lead frame to form traces with different thicknesses, widely available lead frames can be used to form semiconductor packages with integrated passive components. In addition to reducing cost and increasing design flexibility, the example semiconductor packages protect the integrated passive components. Furthermore, the disclosed semiconductor packages conceal the type and arrangement of the passive components.

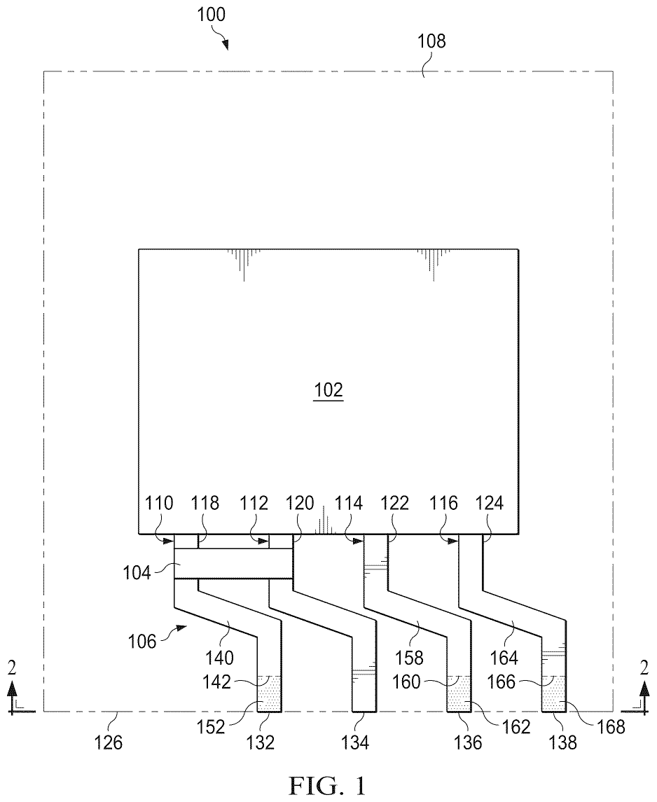

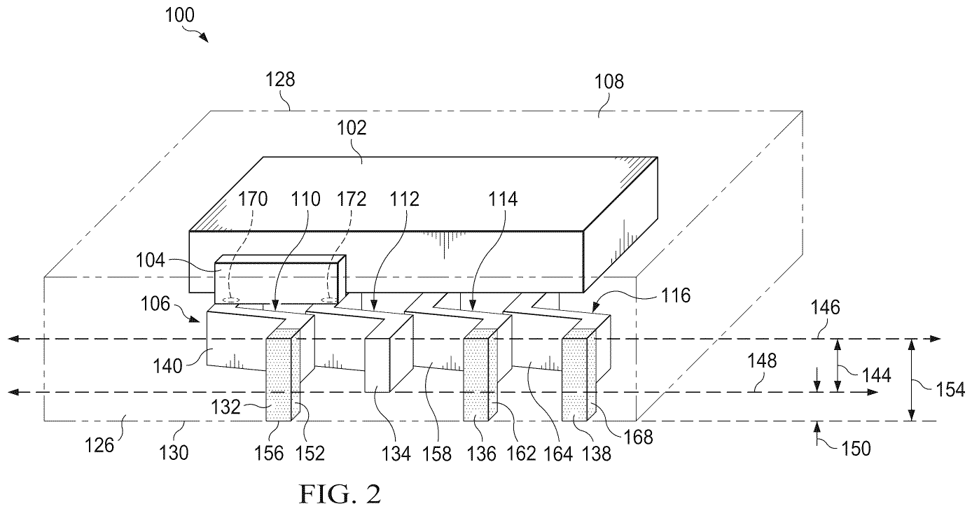

FIGS. 1 and 2 illustrate an example of a semiconductor package 100. The semiconductor package 100 may include quad-flat no-leads (QFN) packages, small outline integrated circuit (SOIC) packages, thin small outline package (TSOP), etc. The semiconductor package 100 includes a semiconductor die 102 and a passive component 104 that are mounted on a lead frame 106. Packaging includes encapsulating the semiconductor die 102, the passive component 104, and the lead frame 106 in mold compound 108 to form the semiconductor package 100. The mold compound 108 is formed of one or more insulating materials, such as organic resins (e.g., epoxy), inorganic resins, and/or other suitable materials.

The lead frame 106 includes a number of traces formed from a conductive sheet. For example, the lead frame 106 includes a first trace 110, a second trace 112, a third trace 114, and a fourth trace 116. The semiconductor die 102 is electrically connected to the lead frame 106. For example, the first trace 110 is electrically attached to the semiconductor die 102 at a first proximate end 118, the second trace 112 is electrically connected to the semiconductor die 102 at a second proximate end 120, the third trace 114 is electrically attached to the semiconductor die 102 at a third proximate end 122, the fourth trace 116 is electrically connected to the semiconductor die 102 at a fourth proximate end 124.

The traces 110-116 terminate at termini at a package edge 126 of the semiconductor package 100. As shown in the cross-sectional view of FIG. 2, the package edge 126 extends from a top surface 128 of the mold compound 108 to a base surface 130 of the mold compound 108 in the longitudinal direction. For purposes of simplification, FIG. 2 employs the same reference numbers to denote the same structure. The package edge 126 is approximately orthogonal to the top surface 128 and/or the base surface 130. The first trace 110 extends to a first terminus 132 at the package edge 126. The second trace 112 extends to a second terminus 134 at the package edge 126. The third trace 114 extends to a third terminus 136 at the package edge 126. The fourth trace 116 extends to a fourth terminus 138 at the package edge 126.

The traces 110-116 have varying thicknesses in the longitudinal direction. For example, a first proximate portion 140 of the first trace 110 extends from the first proximate end 118 to a first distal end 142 in the lateral direction, approximately orthogonal to the longitudinal direction. The first proximate portion 140 has an attenuated thickness 144 in the longitudinal direction. The attenuated thickness 144 is defined between a virtual plane 146 and an intermediary location 148 spaced apart from the base surface 130. In some examples, the virtual plane 146 is defined by a top surface of the lead frame 106. The intermediary location 148 is separated from the base surface 130 by a gap distance 150. In addition to the first proximate portion 140, the first trace 110 includes a first distal portion 152 having a full thickness 154 greater than the attenuated thickness 144 in the longitudinal direction. The first distal portion 152 extends from the first distal end 142 to the first terminus 132 at the package edge 126.

In the example of FIGS. 1 and 2, the full thickness 154 is defined between the virtual plane 146 and the base surface 130. The virtual plane 146 is approximately parallel to the base surface 130. Accordingly, the gap distance 150 is the difference between the attenuated thickness 144 and the full thickness 154. In one example, the full thickness 154 is approximately 200 microns and the attenuated thickness 144 is approximately 80 microns in the longitudinal direction. Thus, the gap distance 150 is approximately 40 microns. An interface is defined between the thicknesses of different portions, such as the first proximate portion 140 and the first distal portion 152. For example, the interface between the attenuated thickness 144 and the full thickness 154 is at the first distal end 142. In some examples, the interface is discontinuous such that the attenuated thickness 144 is constant to the first distal end 142 where the first trace 110 immediately extends to the full thickness 154 of the first distal portion 152. In other examples, the interface is continuous such that the thickness of the first trace 110 slopes from the attenuated thickness 144 to the full thickness 154 at the first distal end 142.

A surface of the first distal portion 152 forms a first pin 156 of the first trace 110. The first pin 156 is accessible through the base surface 130. Multiple traces of the plurality of traces 110-116 form pins at the base surface 130 of the semiconductor package 100. For example, the third trace 114 has a third proximate portion 158 that extends from the third proximate end 122 to a distal end 160. The third proximate portion 158 has the attenuated thickness 144. A third distal portion 162 of the third trace 114 extends from the distal end 160 to the third terminus 136 at the package edge 126. The third distal portion 162 has the full thickness 154. As another example, the fourth trace 116 has a fourth proximate portion 164 that extends from the fourth proximate end 124 to a fourth distal end 166. The fourth proximate portion 158 has the attenuated thickness 144. A fourth distal portion 168 of the fourth trace 116 extends from the fourth distal end 166 to the fourth terminus 138 at the package edge 126. The fourth distal portion 168 has the full thickness 154.

At least one trace of the plurality of traces 110-116 does not have a portion that extends from the virtual plane 146 to the base surface 130. For example, the second trace 112 has the attenuated thickness 144 from the second proximate end 120 to the second terminus 134, such that the second trace forms a second proximate portion. Accordingly, the second trace 112 does not extend beyond the intermediary location 148 toward the base surface 130. Thus, the second trace does not form a pin in the base surface 130 and the second trace 112 is inaccessible external to the semiconductor package 100.

The passive component 104 is electrically connected to two or more of the traces through joints that provide a physical connection or a through connection using another component. For example, the passive component 104 is electrically connected to a first joint 170 of the first proximate portion 140 of the first trace 110 and a second joint 172 of the second trace 112. The passive component 104 may include one or more of a resistor, a capacitor, an inductor, a transformer, an antenna or other type of passive component. For example, suppose a first device is electrically connected to the passive component 104 through the first trace 110 at the first pin 156. If a second device were electrically connected to the passive component 104 at second trace 112, the current intended for the passive component 104 would be able to bypass the passive component 104, thereby shorting the passive component 104. Accordingly, the passive component 104 is coupled between a trace having a pin, for example the first trace 110, and a trace without a pin, in this example the second trace 112. Although the first trace 110 and the second trace 112 are adjacent, the passive component 104 may be coupled between a pair of traces that do not extend to the same edge, here the package edge 126, or be separated by other traces of the plurality of traces 110-116. Additionally, the passive component 104 may be coupled to more than one trace that extend to the intermediary location 148.

The semiconductor die 102, the passive component 104, and the first trace 110 and the second trace 112 that connect the passive component 104 are encapsulated in the mold compound 108. Therefore, the passive component 104 is integrated with the semiconductor package 100. Accordingly, a lead frame 106 is used to form the semiconductor package 100 with the passive component 104 integrated therein. Using the lead frame 106 and one or more integrated passive components 104 reduces cost, increases design flexibility, and protects the passive component 104. In some examples, the first trace 110, the third trace 114, and the fourth trace 116 extend beyond the package edge 126 and through the mold compound 108 to form external pins for the semiconductor package 100.

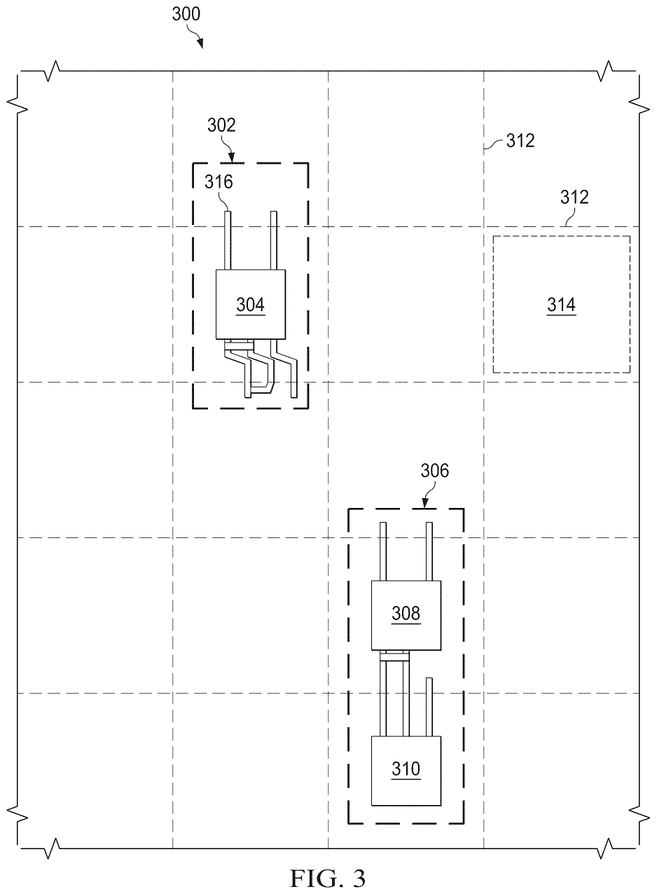

FIG. 3 illustrates an example of semiconductor devices ready for packaging on a lead frame 300 with a strip layout. The lead frame 300 illustrates a relatively evenly spaced matrix having a first semiconductor package 302 including a first semiconductor die 304 and a second semiconductor package 306 including a second semiconductor die 308 and a third semiconductor die 310. For simplicity, two semiconductor packages are described but more or fewer may be arranged on the matrix of the lead frame 300 having similar or dissimilar sizes, arrangements, components, etc.

The first semiconductor package 302 and the second semiconductor package 306 are spaced from one another by saw streets 312 that define a matrix of lead frame sections 314. The saw streets 312 include features of the lead frame 300 that define boundaries of and couple together adjacent pairs of the lead frame sections 314. Accordingly, the first semiconductor package 302 and the second semiconductor package 306 are formed in the lead frame sections 314. Traces 316 extend from the saw streets 312 to the first semiconductor die 304, the second semiconductor die 308, and the third semiconductor die 310. For example, the traces 316 extend from the saw streets 312 to the first semiconductor die 304 of the first semiconductor package 302.

The lead frame 300, the first semiconductor package 302, and the second semiconductor package 306 are encapsulated in a mold compound (not shown). The semiconductor packages can be separated in a later process step by cutting through the saw street 312 to separate the packages, such as the first semiconductor package 302 and the second semiconductor package 306. For example, upon the hardening of the mold compound, a lead frame section of the lead frame sections 314 is singulated to form the first semiconductor package 302 and multiple lead frame sections of the lead frame sections 314 are grouped and singulated to form the second semiconductor package 306.

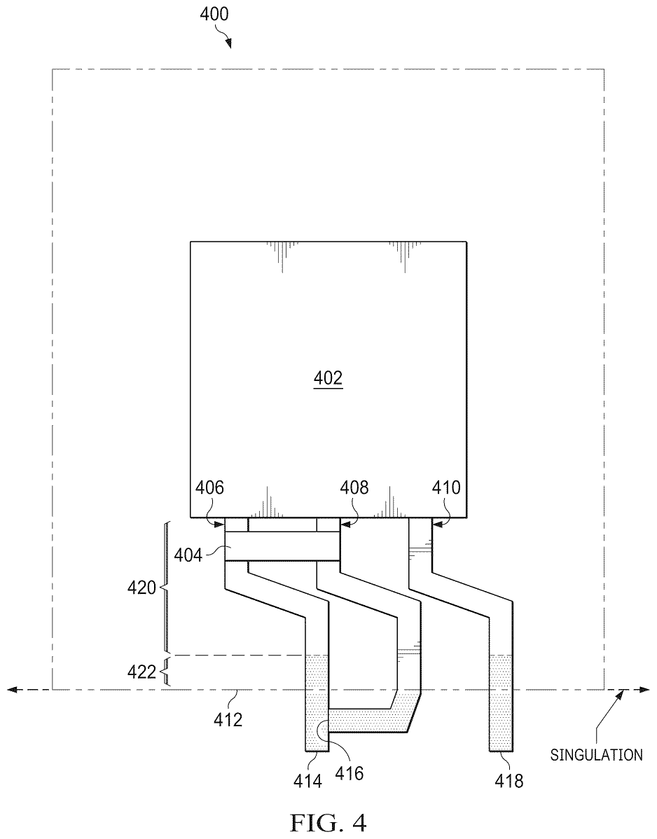

FIG. 4 illustrates an example of a semiconductor package 400 (e.g., the semiconductor package 100 of FIG. 1, the first semiconductor package 302 and the second semiconductor package 306 of FIG. 3) with a branching trace configuration. The semiconductor package 400 includes a semiconductor die 402 (e.g., the semiconductor die 102 of FIG. 1, the first semiconductor die 304, the second semiconductor die 308, and the third semiconductor die 310 of FIG. 3) and the passive component 404 (e.g., the passive component 104 of FIG. 1). The semiconductor die 402 and the passive component 404 are electrically connected by a first trace 406 (e.g., the first trace 110 of FIG. 1), a second trace 408 (e.g., the second trace 112 of FIG. 1), and a third trace 410 (e.g., the third trace 114 of FIG. 1).

The traces 406-410 extend from the semiconductor die 402 to a package edge 412 of the semiconductor package 400. The semiconductor package 400 is singulated at the package edge 412. As a part of lead frame (e.g., the lead frame 106 of FIG. 1, the lead frame 300 of FIG. 3) with a strip layout, the traces extend beyond the package edge 412 of the semiconductor package 400 to endpoints. For example, the first trace 406 ends at a first endpoint 414, the second trace 408 ends at a second endpoint 416, and the third trace 410 ends at a third endpoint 418. In some examples, the branching trace configuration includes the second endpoint 416 of the second trace 408 being attached to the first trace 406 at a branch point between the package edge 412 and the first endpoint 414. Because the semiconductor package 400 is singulated at the package edge 412, the first trace 406 does not contact the second trace 408 within the semiconductor package 400, thereby preventing shorting within the semiconductor package 400.

The full thickness (e.g., the full thickness 154 of FIG. 1) of the traces 406-410 is etched to form proximate portions of the respective traces with an attenuated thickness (e.g., the attenuated thickness 144 of FIG. 1). For example, the first trace 406 has a first proximate portion 420 (e.g., the first proximate portion 140, the third proximate portion 158, the fourth proximate portion 164) having the attenuated thickness. A first distal portion 422 of the first trace 406 is not etched and has the full thickness to form a first pin, of the first trace 406, that is accessible through a base surface (e.g., the base surface 130 of FIG. 1) of the semiconductor package 400. The passive component 404 is affixed to the first trace 406 and the second trace 408 between the semiconductor die 402 and the package edge 412. The second trace 408 is etched from the semiconductor die 402 to the package edge 412 such that the second trace 408 does not form a pin.

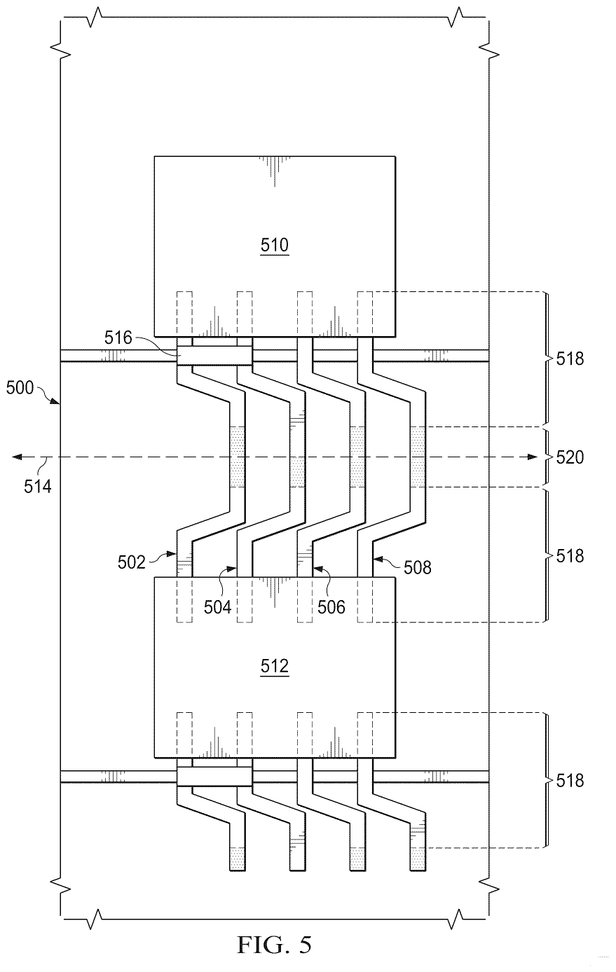

FIG. 5 illustrates an example of semiconductor packages with a shared trace configuration. For example, a lead frame 500 (e.g., the lead frame 106 of FIG. 1, the lead frame 300 of FIG. 3) may include a first trace 502 (e.g., the first trace 110 of FIG. 1, the first trace 406 of FIG. 4), a second trace 504 (e.g., the second trace 112 of FIG. 1, the second trace 408 of FIG. 4), a third trace 506 (e.g., the third trace 114 of FIG. 1, the third trace 410 of FIG. 4), and a fourth trace 508 (e.g., the fourth trace 116 of FIG. 1). Semiconductor dies, including the first semiconductor die 510 and the second semiconductor die 512 are affixed to the traces 502-508 such that the traces 502-508 are shared between the first semiconductor die 510 and the second semiconductor die 512. The first semiconductor die 510 and the second semiconductor die 512 are separated at a singulation plane 514 where the first semiconductor die 510 and the second semiconductor die 512 are cut apart or singulated into individual packages. A passive component 516 (e.g., the passive component 104 of FIG. 1, the passive component 404 of FIG. 4) is affixed between the first semiconductor die 510 and the singulation plane 514.

The traces 502-508 are etched to have proximate portions 518 (e.g., the first proximate portion 140, the third proximate portion 158, the fourth proximate portion 164, a first proximate portion 420 of FIG. 4) with the attenuated thickness (e.g., the attenuated thickness 144 of FIG. 1) and distal portions 520 (e.g., the first distal portion 152, the third distal portion 162, the fourth distal portion 168 of FIG. 1, the first distal portion 422 of FIG. 4) with the full thickness (e.g., the full thickness 154 of FIG. 1). In some examples, the traces 502-508 are supported by tie bars 522 providing structural support and ensuring proper alignment. For example, the tie bars 522 are provided between the proximate portions 518 of the traces 502-508.

One or more of the traces 502-508 form pins at the singulation plane 514. For example, at least one trace, here the first trace 502, affixed to the passive component 516 forms a pin at the singulation plane 514 corresponding to the distal portion 520. The remaining traces, here the second trace 504, affixed to the passive component 516 are etched to the attenuated thickness such that a pin is not formed. Accordingly, of the traces electrically connected to the passive component 516, only one forms a pin at the singulation plane 514 corresponding to an edge (e.g., the package edge 126 of FIG. 1, the package edge 412 of FIG. 4) of a resulting semiconductor package. The tie bars 522 a removed during singulation.

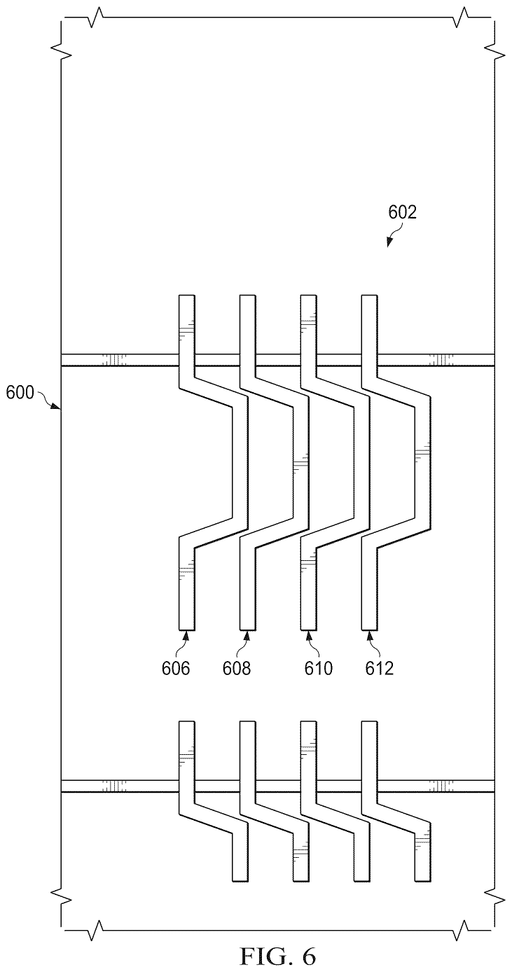

FIGS. 6-12 illustrate stages of a method for fabricating a semiconductor package (e.g., the semiconductor package 100 of FIG. 1, the first semiconductor package 302 and the second semiconductor package 306 of FIG. 3, the semiconductor package 400 of FIG. 4).

FIG. 6 illustrates an example of a first stage of a method of forming a semiconductor package. In the first stage, a lead frame 600 (e.g., the lead frame 106 of FIG. 1, the lead frame 300 of FIG. 3) is provided. The lead frame 600 has a first surface 602 opposite a second surface in a longitudinal direction. The lead frame 600 also includes a tie bar 604 (e.g., the tie bars 522 of FIG. 5). The tie bar 604 extends from one edge of the lead frame 600 to an opposite edge of the lead frame 600. The lead frame 600 forms a plurality of traces, including a first trace 606 (e.g., the first trace 110 of FIG. 1), a second trace 608 (e.g., the second trace 112 of FIG. 1), a third trace 610 (e.g., the third trace 114 of FIG. 1), and a fourth trace 612 (e.g., the fourth trace 116 of FIG. 1). The lead frame 600 is formed of a conductive material, such as copper, palladium, gold, silver, or other appropriate conductive metal or metal alloy with similar properties. For example, the lead frame 600 is formed from a copper sheet having a full thickness (e.g., the full thickness 154 of FIG. 1). In some examples, the tie bar 604 include a first tie bar portion 614 from the one edge of the lead frame 600 to the first trace 606, a second tie bar portion 616 from the first trace 606 to the second trace 608, a third tie bar portion 618 from the second trace 608 to a third trace 610, a fourth tie bar portion 620 from the third trace 610 to the fourth trace 612, and a fifth tie bar portion 622 from the fourth trace 612 to the opposite edge of the lead frame 600.

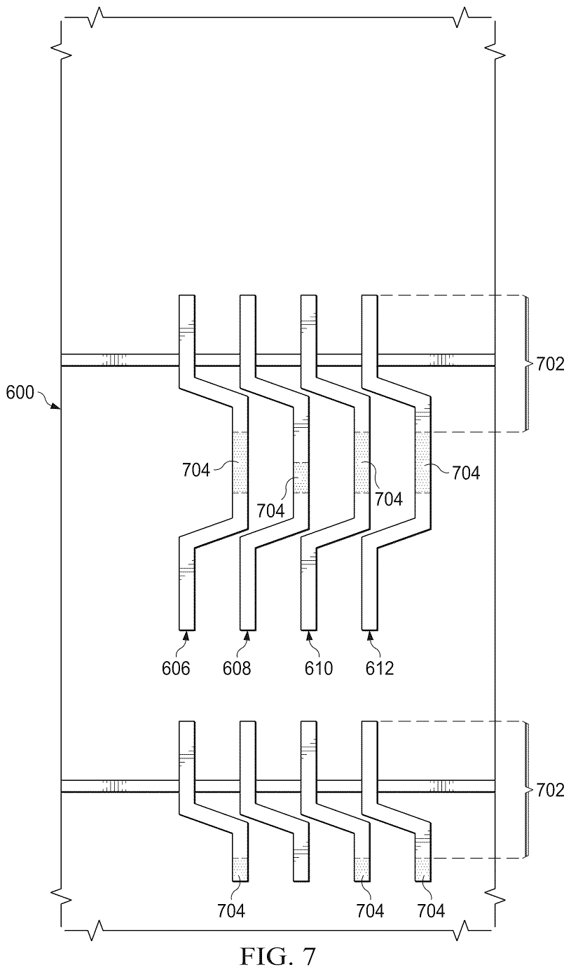

FIG. 7 illustrates an example of a second stage of forming a semiconductor package. In the second stage, portions of the first surface 602 of the one or more of the traces 606-612 are etched from the full thickness to an attenuated thickness (e.g., the attenuated thickness 144 of FIG. 1). For example, proximate portions 702 (e.g., the first proximate portion 140, the third proximate portion 158, the fourth proximate portion 164, a first proximate portion 420 of FIG. 4) are etched from the full thickness to the attenuated thickness. Distal portions 704 of respective traces are not etched and maintain the full thickness. In some examples, the full thickness is less than the initial thickness of the lead frame 600 and the distal portions 704 are etched to the full thickness. The arrangement of the proximate portions 702 and the distal portions 704 is based on the predetermined layout of the semiconductor package.

In some examples, a photoresist is applied to the first surface 602 of the lead frame 600. A photomask is applied having a pattern corresponding to the desired etching to form the respective traces. The photomask is irradiated, and non-irradiated portions of the photoresist are removed. For example, a dry plasma etch is performed to remove the conductive material from the proximate portions 702 of the lead frame 600 to reduce the thickness of the proximate portions 702 to the attenuated thickness. The remaining photomask is then removed.

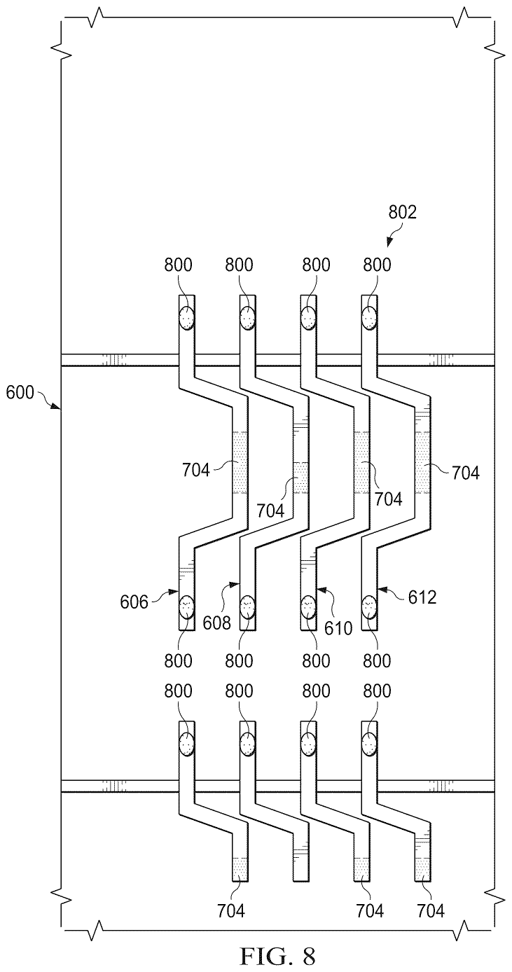

FIG. 8 illustrates an example of a third stage of forming a semiconductor package. In the third stage, a die attach layer 800 is applied to the second surface 802 of the lead frame 600. As an example, the die attach layer 800 may be a polymer film, thermosetting resins, adhesive agent, etc.

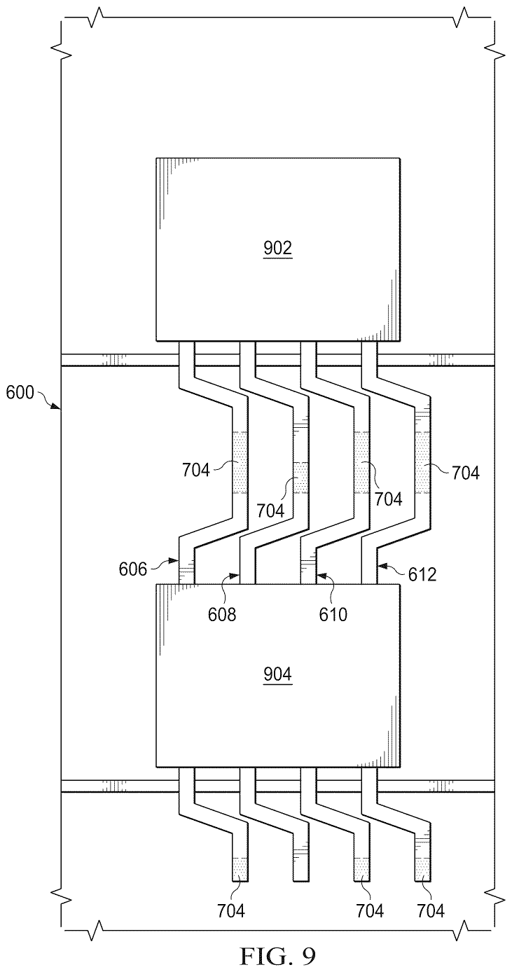

FIG. 9 illustrates an example of a fourth stage of forming a semiconductor package. In the fourth stage, semiconductor dies (e.g. the semiconductor die 102 of FIG. 1, the first semiconductor die 304, the second semiconductor die 308, and the third semiconductor die 310 of FIG. 3, the semiconductor die 402 of FIG. 4, the first semiconductor die 510 and the second semiconductor die 512 of FIG. 5) including a first semiconductor die 902 and a second semiconductor die 904 are mounted on the lead frame 600 at the die attach layer 800.

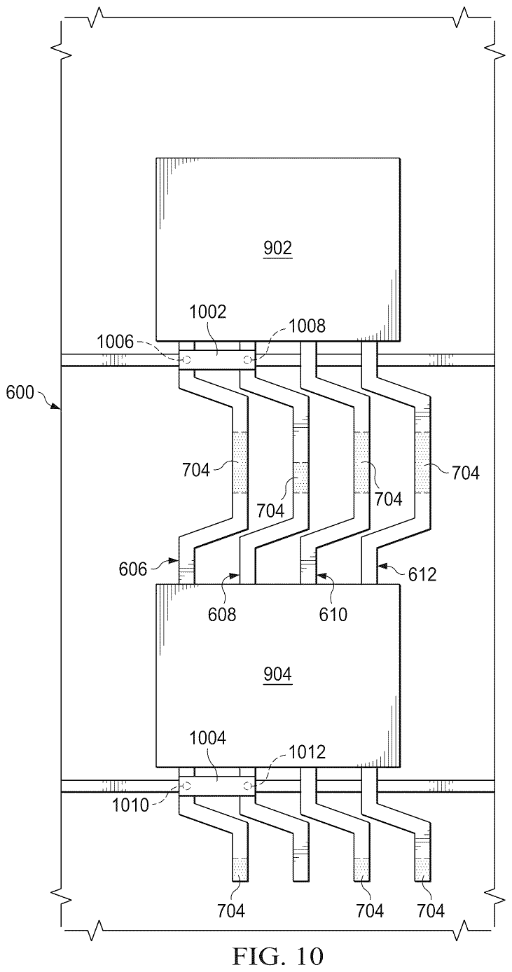

FIG. 10 illustrates an example of a fifth stage of forming a semiconductor package. In the fifth stage, passive components (e.g., the passive component 104 of FIG. 1, the passive component 404 of FIG. 4, the passive component 516 of FIG. 5) including a first passive component 1002 and a second passive component 1004 are electrically connected the lead frame 600. For example, the first passive component 1002 is soldered to a first joint 1006 on the first trace 606 and a second joint 1008 of the second trace 608. Likewise, the second passive component 1004 is soldered to a third joint 1010 on the first trace 606 and fourth joint 1012 on the second trace 608. The first passive component 1002 and the second passive component 1004 may include one or more of an inductor, a capacitor, a resistor, an antenna, a transformer, or other types of passive component.

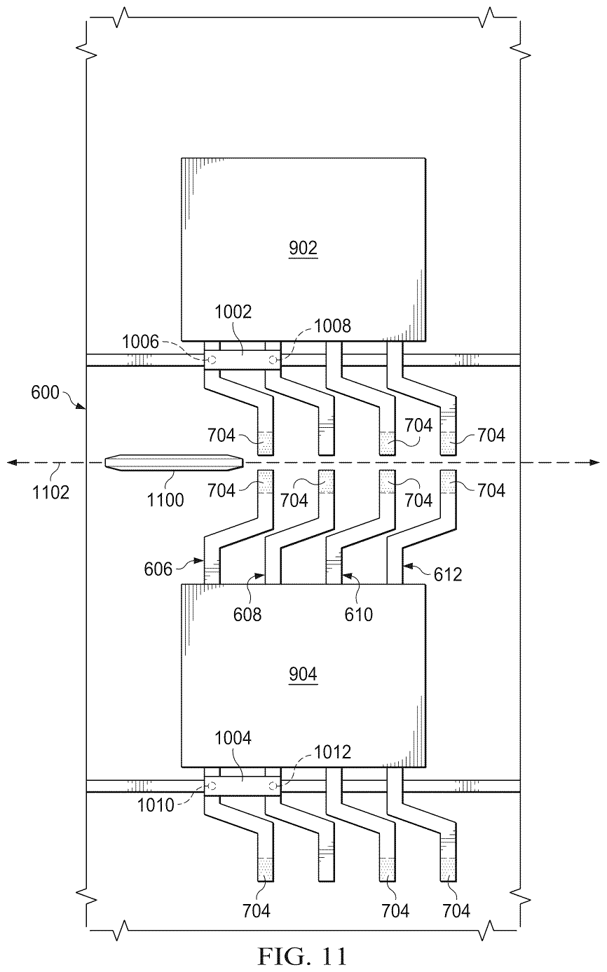

FIG. 11 illustrates an example of a sixth stage of forming a semiconductor package. In the sixth stage, lead frame 600 is singulated into a plurality of semiconductor devices ready for packaging. As one example, a dicing tool 1100, such as a saw, such as a laser saw, a plasma cutter or a diamond saw, is used to singulate the semiconductor devices. The semiconductor devices are singulated along a singulation plane 1102 (e.g., the singulation plane 514 of FIG. 5). Singulating the devices may include cutting the tie bar 604 so that the first tie bar portion 614, the second tie bar portion 616, the third tie bar portion 618, the fourth tie bar portion 620, and the fifth tie bar portion 622 are cut from lead frame 600.

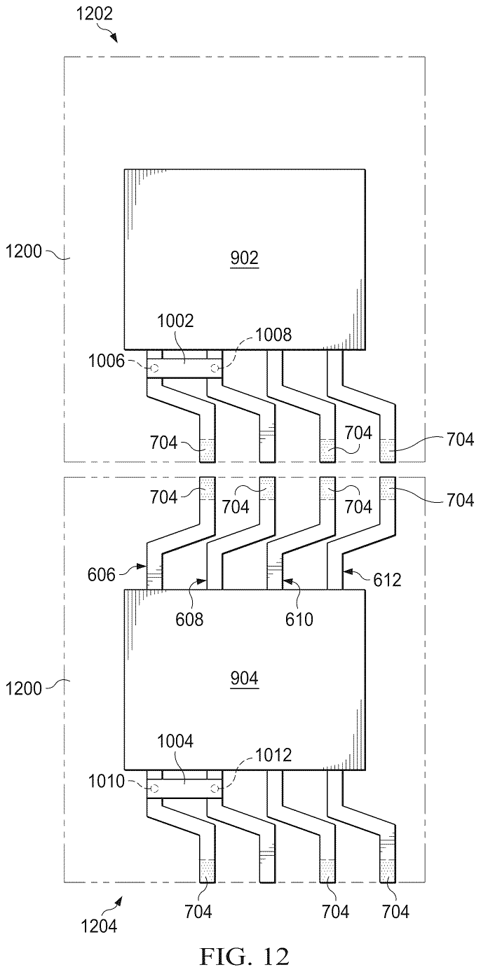

FIG. 12 illustrates an example of a seventh stage of the method for forming the semiconductor package. In the seventh stage, a mold compound 1200 (e.g., the mold compound 108 of FIG. 1) encapsulates the separated semiconductor devices to form semiconductor packages (e.g., the semiconductor package 100 of FIG. 1, the first semiconductor package 302 and the second semiconductor package 306 of FIG. 3, the semiconductor package 400 of FIG. 4). For example, a first semiconductor package 1202 includes the first semiconductor die 902, the first passive component 1002, and the corresponding traces 602-608. A second semiconductor package 1204 includes a second semiconductor die 904, the second passive component 1004, and the traces 602-608. In some examples, the mold compound 1200 is applied in a mold flow operation. Alternatively, the timing of the singulation step of the sixth stage in FIG. 11 and the molding step of the seventh stage in FIG. 12 can be reversed so that molding of the devices occurs prior to device singulation. The tie bar 604 is removed prior to the molding of the devices.

In some examples, punching or drilling operations are formed through conventional punching or drilling operations to form holes through the mold compound 1200 to make the pins corresponding to the distal portions 704 electrically accessible. After drilling or punching the holes in the mold compound 1200 may then be plated with a conductive material to make the holes in the mold compound 1200 conductive to form the pins. Traces, such as the second trace 608 that do not terminate in a pin are not subjected to punching.

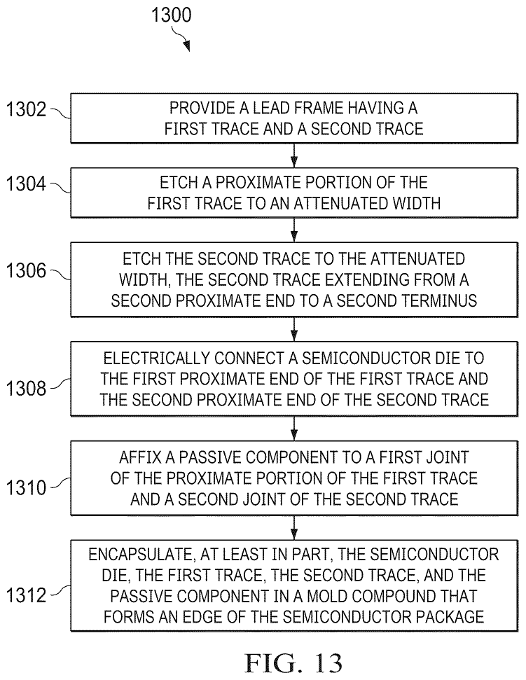

FIG. 13 illustrates an example process flow of a method 1300 for forming a semiconductor package (e.g., the semiconductor package 100 of FIG. 1, the first semiconductor package 302 and the second semiconductor package 306 of FIG. 3, the semiconductor package 400 of FIG. 4, the first semiconductor package 1202, the second semiconductor package 1204 of FIG. 12).

At 1302, the method 1300 includes providing a lead frame (e.g., the lead frame 106 of FIG. 1, the lead frame 300 of FIG. 3, the lead frame 600 of FIG. 6) having a first trace (e.g., the first trace 110 of FIG. 1, the first trace 606 of FIG. 6) and a second trace (e.g., the second trace 112 of FIG. 1, the second trace 608 of FIG. 6).

At 1304, the method 1300 etching a proximate portion (e.g., the first proximate portion 140, the third proximate portion 158, the fourth proximate portion 164, a first proximate portion 420 of FIG. 4, the proximate portions 702 of FIG. 7) of the first trace to an attenuated thickness (e.g., the attenuated thickness 144 of FIG. 1). The proximate portion extends from a first proximate end (e.g., the first proximate end 118 of FIG. 1) to a distal end of the proximate portion (e.g., the first distal end 142). The first trace further comprises a distal portion (e.g., first distal portion 152 of FIG. 2) that extends from the distal end to a first terminus (e.g., the first terminus 132) having a full thickness (e.g., the full thickness 154 of FIG. 1) greater than the attenuated thickness. In some examples, the etching is selectively performed using masking/lithography techniques.

At 1306, the method 1300 includes etching the second trace to the attenuated thickness. The second trace extends from a second proximate end (e.g., the second proximate end 120 of FIG. 1) to a second terminus (e.g., the second terminus 134 of FIG. 1).

At 1308, the method 1300 includes electrically connecting a semiconductor die (e.g. the semiconductor die 102 of FIG. 1, the first semiconductor die 304, the second semiconductor die 308, and the third semiconductor die 310 of FIG. 3, the semiconductor die 402 of FIG. 4, the first semiconductor die 510 and the second semiconductor die 512 of FIG. 5, the first semiconductor die 902, and the second semiconductor die 904) to the first proximate end of the first trace and the second proximate end of the second trace.

At 1310, the method 1300 includes affixing a passive component (e.g., the passive component 104 of FIG. 1, the passive component 404 of FIG. 4, the passive component 516 of FIG. 5, the first passive component 1002, and the second passive component 1004 of FIG. 10) to a first joint (e.g., the first joint 170 of FIG. 1, the first joint 1006 and the third joint 1010 of FIG. 10) of the proximate portion of the first trace and a second joint (e.g., the second joint 172 of FIG. 1, the second joint 1008 and the fourth joint 1012 of FIG. 10) of the second trace.

At 1312, the method 1300 includes encapsulating, at least in part, the semiconductor die, the first trace, the second trace, and the passive component in a mold compound (e.g., the mold compound 108 of FIG. 1, the mold compound 1200 of FIG. 12) that forms a package edge (e.g., the package edge 126 of FIG. 1, the package edge 412 of FIG. 4) of the semiconductor package. As the passive component is encapsulated in the mold compound with semiconductor dies and traces, the passive component is integrated with the semiconductor package. The traces are etched to have different thicknesses such that one or more of the traces that are electrically connected to the passive component do not form pins in the semiconductor package. Integrating the passive components with semiconductor package, conceal the type and arrangement of the passive components. Additionally, a standard lead frame, such a routable lead frame, can be used rather than a stacked substrate which reduces cost and increases design flexibility.

What have been described above are examples. It is, of course, not possible to describe every conceivable combination of components or methodologies, but one of ordinary skill in the art will recognize that many further combinations and permutations are possible. Accordingly, the disclosure is intended to embrace all such alterations, modifications, and variations that fall within the scope of this application, including the appended claims. As used herein, the term “includes” means includes but not limited to, the term “including” means including but not limited to. The term “based on” means based at least in part on. Additionally, where the disclosure or claims recite “a,” “an,” “a first,” or “another” element, or the equivalent thereof, it should be interpreted to include one or more than one such element, neither requiring nor excluding two or more such elements.

In this description, unless otherwise stated, “about,” “approximately” or “substantially” preceding a parameter means being within +/−10 percent of that parameter. Modifications are possible in the described embodiments, and other embodiments are possible, within the scope of the claims.

Further, unless specified otherwise, “first”, “second”, or the like are not intended to imply a temporal aspect, a spatial aspect, an ordering, etc. Rather, such terms are merely used as identifiers, names, etc. for features, elements, items, etc. For example, a first channel and a second channel generally correspond to channel A and channel B or two different or two identical channels or the same channel. Additionally, “comprising”, “comprises”, “including”, “includes”, or the like generally means comprising or including, but not limited to.

It will be appreciated that several of the above-disclosed and other features and functions, or alternatives or varieties thereof, may be desirably combined into many other different systems or applications. Also, that various presently unforeseen or unanticipated alternatives, modifications, variations or improvements therein may be subsequently made by those skilled in the art which are also intended to be encompassed by the following claims.

What is claimed is:

1. A semiconductor package comprising:
a semiconductor die;
a first trace having a proximate portion extending from a first proximate end, electrically connected to the semiconductor die, to a distal end, and a distal portion extending from the distal end to a first terminus at a package edge of the semiconductor package, wherein the proximate portion has an attenuated thickness and the distal portion has a full thickness greater than the attenuated thickness;
a second trace extending from a second proximate end, electrically connected to the semiconductor die, to a second terminus at the package edge of the semiconductor package, wherein the second trace has the attenuated thickness; and
a passive component electrically connected to the first trace and the second trace.

2. The semiconductor package of claim 1, further comprising:
a mold compound encapsulating the semiconductor die, the first trace, the second trace, and the passive component.

3. The semiconductor package of claim 1, wherein the package edge of the semiconductor package extends from a base surface to a top surface, and wherein the full thickness extends from a virtual plane approximately parallel to the base surface.

4. The semiconductor package of claim 3, wherein the attenuated thickness extends from the virtual plane to an intermediary location spaced apart from the base surface.

5. The semiconductor package of claim 1, wherein the distal portion forms a pin of the first trace that is accessible external to the semiconductor package.

6. The semiconductor package of claim 1, wherein the second trace is inaccessible external to the semiconductor package.

7. The semiconductor package of claim 1, wherein the passive component is electrically connected to a first joint of the proximate portion of the first trace and a second joint of the second trace.

8. The semiconductor package of claim 1, wherein the passive component is a resistor, a capacitor, an inductor, a transformer, or an antenna.

9. The semiconductor package of claim 1, wherein the attenuated thickness is approximately 80 microns and the full thickness is approximately 200 microns.

10. A method of fabricating a semiconductor package comprising:
providing a lead frame having a first trace and a second trace, wherein the first trace has a proximate portion extending from a first proximate end to a distal end, and a distal portion extending from the distal end to a first terminus, wherein the proximate portion has an attenuated thickness and the distal portion has a full thickness greater than the attenuated thickness, wherein the second trace extending from a second proximate end to a second terminus, wherein the second trace has the attenuated thickness;
electrically connecting a semiconductor die to the first proximate end of the first trace and the second proximate end of the second trace;
affixing a passive component to a first joint of the proximate portion of the first trace and a second joint of the second trace; and
encapsulating, at least in part, the semiconductor die, the first trace, the second trace, and the passive component in a mold compound that forms a package edge of the semiconductor package.

11. The method of claim 10, wherein the package edge of the semiconductor package extends from a base surface to a top surface, and wherein the full thickness extends from a virtual plane approximately parallel to the base surface.

12. The method of claim 11, wherein the attenuated thickness extends from the virtual plane to an intermediary location spaced apart from the base surface.

13. The method of claim 10, wherein the distal portion forms a pin of the first trace that is accessible external to the semiconductor package.

14. The method of claim 10, wherein the passive component is a resistor, a capacitor, an inductor, a transformer, or an antenna.

15. The method of claim 10, wherein the attenuated thickness is approximately 80 microns and the full thickness is approximately 200 microns.

16. A method of fabricating a semiconductor package, the method comprising:
providing a lead frame having a first trace and a second trace;
etching a proximate portion of the first trace to an attenuated thickness, the proximate portion extending from a first proximate end to a distal end, wherein the first trace further comprises a distal portion extending from the distal end to a first terminus having a full thickness greater than the attenuated thickness;
etching the second trace to the attenuated thickness, the second trace extending from a second proximate end to a second terminus;
electrically connecting a semiconductor die to the first proximate end of the first trace and the second proximate end of the second trace;
affixing a passive component to a first joint of the proximate portion of the first trace and a second joint of the second trace; and
encapsulating, at least in part, the semiconductor die, the first trace, the second trace, and the passive component in a mold compound that forms a package edge of the semiconductor package.

17. The method of claim 16, wherein the package edge of the semiconductor package extends from a base surface to a top surface, and wherein the full thickness extends from a virtual plane approximately parallel to the base surface.

18. The method of claim 17, wherein the attenuated thickness extends from the virtual plane to an intermediary location spaced apart from the base surface.

19. The method of claim 16, wherein the passive component is a resistor, a capacitor, an inductor, a transformer, or an antenna.

20. The method of claim 16, wherein the attenuated thickness is approximately 80 microns and the full thickness is approximately 200 microns.
